(19) United States
(12) Patent Application Publication
(10) Pub. No.: US 2023/0422495 A1
(43) Pub. Date: Dec. 28, 2023

(54) MEMORY STRUCTURE

(71) Applicant: Powerchip Semiconductor Manufacturing Corporation, Hsinchu (TW)

(72) Inventor: Zih-Song Wang, Nantou County (TW)

(73) Assignee: Powerchip Semiconductor Manufacturing Corporation, Hsinchu (TW)

(21) Appl. No.: 17/945,077

(22) Filed: Sep. 14, 2022

(30) Foreign Application Priority Data
Jun. 23, 2022 (TW) 111123344

(51) Int. Cl. H01L 27/11556; H01L 27/11582

(52) U.S. Cl. CPC H01L 27/11556; H01L 27/11582

(57) ABSTRACT

A memory structure including the following components is provided. A first dielectric layer is disposed on a substrate. A first memory cell includes a first conductive layer, a second conductive layer, a first channel layer, and a first charge storage layer. The first conductive layer and the second conductive layer are sequentially stacked on the first dielectric layer and are electrically insulated from each other. The first channel layer is disposed on one side of the first conductive layer and one side of the second conductive layer. The first charge storage layer is disposed between the first conductive layer and the first channel layer. A first bit line is disposed in the first dielectric layer and is connected to the first channel layer. A source line is disposed above the first channel layer and is connected to the first channel layer.

### CROSS-REFERENCE TO RELATED APPLICATION

This application claims the priority benefit of Taiwan application serial no. 111123344, filed on Jun. 23, 2022. The entirety of the above-mentioned patent application is hereby incorporated by reference herein and made a part of this specification.

### BACKGROUND

### Technical Field

The invention relates to a semiconductor structure, and particularly relates to a memory structure.

### Description of Related Art

The non-volatile memory (e.g., flash memory) can perform multiple data operations such as storing, reading, and erasing, and has advantages such as the stored data does not disappear when the power supply is interrupted, short data access time, and low power consumption, so the non-volatile memory has become a memory widely used in personal computers and electronic products. However, how to reduce the operating voltage of the memory device is the goal of continuous efforts.

### SUMMARY

The invention provides a memory structure, which can be operated at low voltage.

The invention provides a memory structure, which includes a substrate, a first dielectric layer, a first memory cell, a first bit line, and a source line. The first dielectric layer is disposed on the substrate. The first memory cell includes a first conductive layer, a second conductive layer, a first channel layer, and a first charge storage layer. The first conductive layer and the second conductive layer are sequentially stacked on the first dielectric layer and are electrically insulated from each other. The first channel layer is disposed on one side of the first conductive layer and one side of the second conductive layer. The first conductive layer and the second conductive layer are electrically insulated from the first channel layer. The first charge storage layer is disposed between the first conductive layer and the first channel layer. The first bit line is disposed in the first dielectric layer and is connected to the first channel layer. The source line is disposed above the first channel layer and is connected to the first channel layer.

According to an embodiment of the invention, in the memory structure, the memory structure may be a three-dimensional (3D) NOR flash memory structure.

According to an embodiment of the invention, in the memory structure, the first channel layer may be disposed between the source line and the first bit line.

According to an embodiment of the invention, in the memory structure, the first memory cell may further include a second dielectric layer, a third dielectric layer, and a fourth dielectric layer. The second dielectric layer is disposed between the first conductive layer and the second conductive layer. The third dielectric layer is disposed between the first conductive layer and the first channel layer and between the second conductive layer and the first channel layer. The fourth dielectric layer is disposed between the first charge storage layer and the first conductive layer. The memory structure may further include a fifth dielectric layer. The fifth dielectric layer is disposed on the second conductive layer. The source line may be disposed in the fifth dielectric layer.

According to an embodiment of the invention, the memory structure may further include a second memory cell and a second bit line. The second memory cell may include a third conductive layer, a fourth conductive layer, a second channel layer, and a second charge storage layer. The third conductive layer and the fourth conductive layer are sequentially stacked on the fifth dielectric layer and are electrically insulated from each other. The second channel layer is disposed on one side of the third conductive layer and one side of the fourth conductive layer and is connected to the source line. The third conductive layer and the fourth conductive layer are electrically insulated from the second channel layer. The second charge storage layer is disposed between the fourth conductive layer and the second channel layer. The second bit line is disposed above the second channel layer and is connected to the second channel layer.

According to an embodiment of the invention, in the memory structure, the first memory cell and the second memory cell may be sequentially stacked on the substrate.

According to an embodiment of the invention, in the memory structure, the first memory cell and the second memory cell may share the source line.

According to an embodiment of the invention, in the memory structure, the second channel layer may be disposed between the second bit line and the source line.

According to an embodiment of the invention, in the memory structure, the second memory cell may further include a sixth dielectric layer, a seventh dielectric layer, and an eighth dielectric layer. The sixth dielectric layer is disposed between the third conductive layer and the fourth conductive layer. The seventh dielectric layer is disposed between the third conductive layer and the second channel layer and between the fourth conductive layer and the second channel layer. The eighth dielectric layer is disposed between the second charge storage layer and the fourth conductive layer. The memory structure may further include a ninth dielectric layer disposed on the fourth conductive layer. The second bit line may be disposed in the ninth dielectric layer.

According to an embodiment of the invention, the memory structure may further include a first dielectric pillar and a second dielectric pillar. The first dielectric pillar is disposed in the first channel layer and is surrounded by the first channel layer. The second dielectric pillar is disposed in the second channel layer and is surrounded by the second channel layer.

The invention provides another memory structure, which includes a substrate, a first dielectric layer, a first memory cell, a first source line, and a bit line. The first dielectric layer is disposed on the substrate. The first memory cell includes a first conductive layer, a second conductive layer, a first channel layer, and a first charge storage layer. The first conductive layer and the second conductive layer are sequentially stacked on the first dielectric layer and are electrically insulated from each other. The first channel layer is disposed on one side of the first conductive layer and one side of the second conductive layer. The first conductive layer and the second conductive layer are electrically insulated from the first channel layer. The first charge storage layer is disposed between the second conductive layer and the first channel layer. The first source line is disposed in the first dielectric layer and is connected to the first channel layer. The bit line is disposed above the first channel layer and is connected to the first channel layer.

According to another embodiment of the invention, in the memory structure, the memory structure may be a 3D NOR flash memory structure.

According to another embodiment of the invention, in the memory structure, the first channel layer may be disposed between the bit line and the first source line.

According to another embodiment of the invention, in the memory structure, the first memory cell may further include a second dielectric layer, a third dielectric layer, and a fourth dielectric layer. The second dielectric layer is disposed between the first conductive layer and the second conductive layer. The third dielectric layer is disposed between the first conductive layer and the first channel layer and between the second conductive layer and the first channel layer. The fourth dielectric layer is disposed between the first charge storage layer and the second conductive layer. The memory structure may further include a fifth dielectric layer. The fifth dielectric layer is disposed on the second conductive layer. The bit line may be disposed in the fifth dielectric layer.

According to another embodiment of the invention, the memory structure may further include a second memory cell and a second source line. The second memory cell may include a third conductive layer, a fourth conductive layer, a second channel layer, and a second charge storage layer. The third conductive layer and the fourth conductive layer are sequentially stacked on the fifth dielectric layer and are electrically insulated from each other. The second channel layer is disposed on one side of the third conductive layer and one side of the fourth conductive layer and is connected to the bit line. The third conductive layer and the fourth conductive layer are electrically insulated from the second channel layer. The second charge storage layer is disposed between the third conductive layer and the second channel layer. The second source line is disposed above the second channel layer and is connected to the second channel layer.

According to another embodiment of the invention, in the memory structure, the first memory cell and the second memory cell may be sequentially stacked on the substrate.

According to another embodiment of the invention, in the memory structure, the first memory cell and the second memory cell may share the bit line.

According to another embodiment of the invention, in the memory structure, the second channel layer may be disposed between the second source line and the bit line.

According to another embodiment of the invention, in the memory structure, the second memory cell may further include a sixth dielectric layer, a seventh dielectric layer, and an eighth dielectric layer. The sixth dielectric layer is disposed between the third conductive layer and the fourth conductive layer. The seventh dielectric layer is disposed between the third conductive layer and the second channel layer and between the fourth conductive layer and the second channel layer. The eighth dielectric layer is disposed between the second charge storage layer and the third conductive layer. The memory structure may further include a ninth dielectric layer. The ninth dielectric layer is disposed on the fourth conductive layer. The second source line may be disposed in the ninth dielectric layer.

According to another embodiment of the invention, the memory structure may further include a first dielectric pillar and a second dielectric pillar. The first dielectric pillar is disposed in the first channel layer and is surrounded by the first channel layer. The second dielectric pillar is disposed in the second channel layer and is surrounded by the second channel layer.

Based on the above description, in the memory structure according to the invention, the first memory cell includes the first conductive layer and the second conductive layer, and the first conductive layer and the second conductive layer are sequentially stacked on the first dielectric layer and are electrically insulated from each other. Therefore, the first memory cell is a memory cell structure with a split gate, and there is no charge storage layer between the conductive layer used as the word line (gate) and the channel layer, thereby reducing the operating voltage. In this way, the memory structure can be operated at low voltage. In some embodiments, other memory cell can be stacked on the first memory cell, thereby reducing the bit cost.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic circuit diagram illustrating a memory structure according to some embodiments of the invention.

FIG. 2 is a cross-sectional view of a memory cell in FIG. 1.

FIG. 3 is a schematic circuit diagram illustrating a memory structure according to other embodiments of the invention.

FIG. 4 is a cross-sectional view of a memory cell in FIG. 3.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

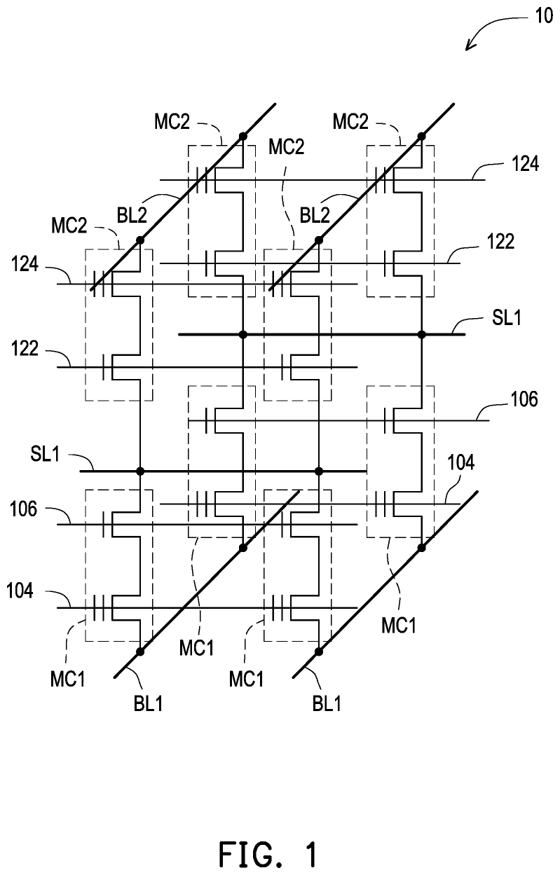

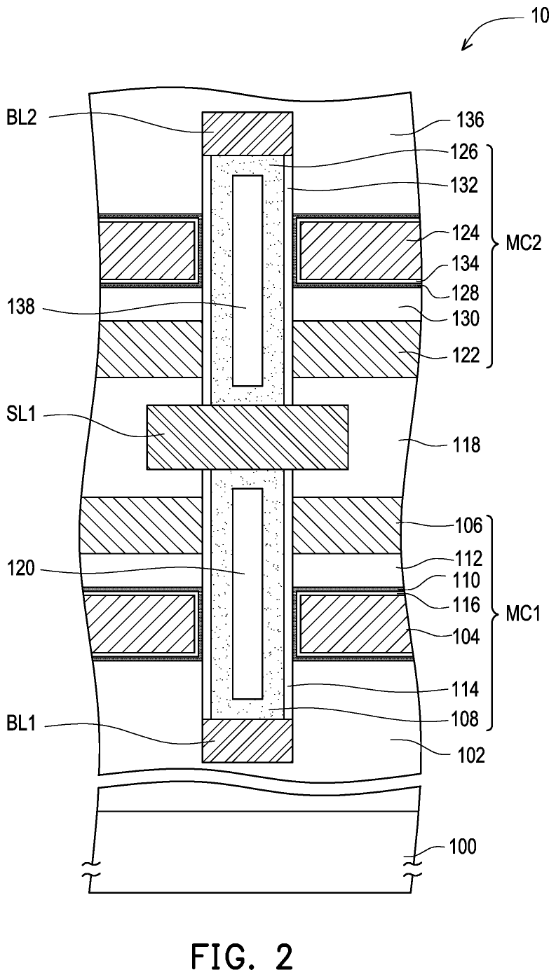

FIG. 1 is a schematic circuit diagram illustrating a memory structure according to some embodiments of the invention. FIG. 2 is a cross-sectional view of a memory cell in FIG. 1.

Referring to FIG. 1 and FIG. 2, the memory structure 10 includes a substrate 100, a dielectric layer 102, a memory cell MC1, a bit line BL1, and a source line SL1. In some embodiments, the memory structure 10 may be a 3D NOR flash memory structure. The substrate 100 may be a semiconductor substrate such as a silicon substrate. The dielectric layer 102 is disposed on the substrate 100. The dielectric layer 102 may be a single-layer structure or a multilayer structure. The material of the dielectric layer 102 is, for example, silicon oxide.

The memory cell MC1 includes a conductive layer 104, a conductive layer 106, a channel layer 108, and a charge storage layer 110. The conductive layer 104 and the conductive layer 106 are sequentially stacked on the dielectric layer 102 and are electrically insulated from each other. The conductive layer 104 can be used as a memory gate. The material of the conductive layer 104 is, for example, tungsten. The conductive layer 106 can be used as a word line. The material of the conductive layer 106 is, for example, doped polysilicon.

The channel layer 108 is disposed on one side of the conductive layer 104 and one side of the conductive layer 106. In addition, the conductive layer 104 and the conductive layer 106 are electrically insulated from the channel layer 108. In some embodiments, the conductive layer 104 may surround the channel layer 108, and the conductive layer 106 may surround the channel layer 108. The material of the channel layer 108 is, for example, a semiconductor material such as polysilicon.

The charge storage layer 110 is disposed between the conductive layer 104 and the channel layer 108. In some embodiments, the charge storage layer 110 may be further disposed between the conductive layer 104 and the dielectric layer 102 and between the conductive layer 106 and the conductive layer 104. The material of the charge storage layer 110 is, for example, a charge trapping material such as silicon nitride.

In some embodiments, the memory cell MC1 may further include a dielectric layer 112, a dielectric layer 114, and a dielectric layer 116. The dielectric layer 112 is disposed between the conductive layer 104 and the conductive layer 106. In some embodiments, the dielectric layer 112 may be further disposed between the conductive layer 106 and the charge storage layer 110. The material of the dielectric layer 112 is, for example, silicon oxide.

The dielectric layer 114 is disposed between the conductive layer 104 and the channel layer 108 and between the conductive layer 106 and the channel layer 108. In some embodiments, the dielectric layer 114 may be further disposed between the dielectric layer 102 and the channel layer 108 and between the dielectric layer 112 and the channel layer 108. The material of the dielectric layer 114 is, for example, silicon oxide.

The dielectric layer 116 is disposed between the charge storage layer 110 and the conductive layer 104. The material of the dielectric layer 116 is, for example, silicon oxide.

In some embodiments, the conductive layer 104 and the conductive layer 106 may be electrically insulated from each other by at least one of the dielectric layer 112, the charge storage layer 110, and the dielectric layer 116. In some embodiments, the conductive layer 104 may be electrically insulated from the channel layer 108 by at least one of the dielectric layer 114, the charge storage layer 110, and the dielectric layer 116. In some embodiments, the conductive layer 106 may be electrically insulated from the channel layer 108 by the dielectric layer 114.

The bit line BL1 is disposed in the dielectric layer 102 and is connected to the channel layer 108. The material of the bit line BL1 is, for example, doped polysilicon or tungsten. The source line SL1 is disposed above the channel layer 108 and is connected to the channel layer 108. The material of the source line SL1 is, for example, doped polysilicon or tungsten. In addition, the channel layer 108 may be disposed between the source line SL1 and the bit line BL1.

In some embodiments, the memory structure 10 may further include at least one of a dielectric layer 118 and a dielectric pillar 120. The dielectric layer 118 is disposed on the conductive layer 106. The source line SL1 may be disposed in the dielectric layer 118. In some embodiments, the dielectric layer 114 may be further disposed between the dielectric layer 118 and the channel layer 108. The dielectric layer 118 may be a single-layer structure or a multilayer structure. The material of the dielectric layer 118 is, for example, silicon oxide.

The dielectric pillar 120 is disposed in the channel layer 108 and is surrounded by the channel layer 108. The material of the dielectric pillar 120 is, for example, silicon oxide.

In some embodiments, the memory structure 10 may further include a memory cell MC2 and a bit line BL2. The memory cell MC1 and the memory cell MC2 may be sequentially stacked on the substrate 100, thereby reducing the bit cost. In addition, the memory cell MC1 and the memory cell MC2 may share the source line SL1. In some embodiments, the memory cell MC2 may be a mirror structure of the memory cell MC1.

The memory cell MC2 may include a conductive layer 122, a conductive layer 124, a channel layer 126, and a charge storage layer 128. The conductive layer 122 and the conductive layer 124 are sequentially stacked on the dielectric layer 118 and are electrically insulated from each other. The conductive layer 122 can be used as a word line. The material of the conductive layer 122 is, for example, doped polysilicon. The conductive layer 124 can be used as a memory gate. The material of the conductive layer 124 is, for example, tungsten.

The channel layer 126 is disposed on one side of the conductive layer 122 and one side of the conductive layer 124 and is connected to the source line SL1. In addition, the conductive layer 122 and the conductive layer 124 are electrically insulated from the channel layer 126. In some embodiments, the conductive layer 122 may surround the channel layer 126, and the conductive layer 124 may surround the channel layer 126. The material of the channel layer 126 is, for example, a semiconductor material such as polysilicon.

The charge storage layer 128 is disposed between the conductive layer 124 and the channel layer 126. In some embodiments, the charge storage layer 128 may be further disposed between the conductive layer 124 and the conductive layer 122. The material of the charge storage layer 128 is, for example, a charge trapping material such as silicon nitride.

In some embodiments, the memory cell MC2 may further include a dielectric layer 130, a dielectric layer 132, and a dielectric layer 134. The dielectric layer 130 is disposed between the conductive layer 122 and the conductive layer 124. In some embodiments, the dielectric layer 130 may be further disposed between the conductive layer 122 and the charge storage layer 128. The material of the dielectric layer 130 is, for example, silicon oxide.

The dielectric layer 132 is disposed between the conductive layer 122 and the channel layer 126 and between the conductive layer 124 and the channel layer 126. In some embodiments, the dielectric layer 132 may be further disposed between the dielectric layer 130 and the channel layer 126 and between the dielectric layer 118 and the channel layer 126. The material of the dielectric layer 132 is, for example, silicon oxide.

The dielectric layer 134 is disposed between the charge storage layer 128 and the conductive layer 124. The material of the dielectric layer 134 is, for example, silicon oxide.

In some embodiments, the conductive layer 122 and the conductive layer 124 may be electrically insulated from each other by at least one of the dielectric layer 130, the charge storage layer 128, and the dielectric layer 134. In some embodiments, the conductive layer 122 may be electrically insulated from the channel layer 126 by the dielectric layer 132. In some embodiments, the conductive layer 124 may be electrically insulated from the channel layer 126 by at least one of the dielectric layer 132, the charge storage layer 128, and the dielectric layer 134.

The bit line BL2 is disposed above the channel layer 126 and is connected to the channel layer 126. The material of the bit line BL2 is, for example, doped polysilicon or tungsten. In addition, the channel layer 126 may be disposed between the bit line BL2 and the source line SL1.

In some embodiments, the memory structure 10 may further include at least one of a dielectric layer 136 and a dielectric pillar 138. The dielectric layer 136 is disposed on the conductive layer 124. The bit line BL2 may be disposed in the dielectric layer 136. In some embodiments, the charge storage layer 128 may be further disposed between the conductive layer 124 and the dielectric layer 136. In some embodiments, the dielectric layer 132 may be further disposed between the dielectric layer 136 and the channel layer 126. The dielectric layer 136 may be a single-layer structure or a multilayer structure. The material of the dielectric layer 136 is, for example, silicon oxide.

The dielectric pillar 138 is disposed in the channel layer 126 and is surrounded by the channel layer 126. The material of the dielectric pillar 138 is, for example, silicon oxide.

In some embodiments, referring to FIG. 1, the memory structure 10 may include a plurality of memory cells MC1 and a plurality of memory cells MC2, but the number of the memory cells MC1 and the number of the memory cells MC2 are not limited to those in the figure. In addition, each memory cell MC1 and each memory cell MC2 can be independently operated. In some embodiments, although not shown in FIG. 1 and FIG. 2, the memory cells MC1 and the memory cells MC2 may be alternately stacked on the substrate 100, thereby further reducing the bit cost.

Based on the above embodiments, in the memory structure 10, the memory cell MC1 includes the conductive layer 104 and the conductive layer 106, and the conductive layer 104 and the conductive layer 106 are sequentially stacked on the dielectric layer 102 and are electrically insulated from each other. Therefore, the memory cell MC1 is a memory cell structure with a split gate, and there is no charge storage layer between the conductive layer 106 used as the word line (gate) and the channel layer 108, thereby reducing the operating voltage. In this way, the memory structure 10 can be operated at low voltage. In some embodiments, other memory cell (e.g., memory cell MC2) can be stacked on the memory cell MC1, thereby reducing the bit cost.

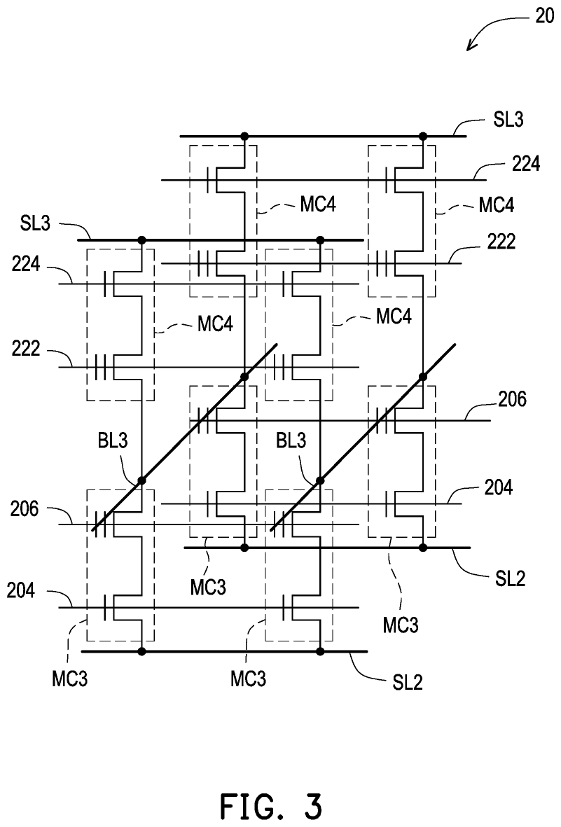

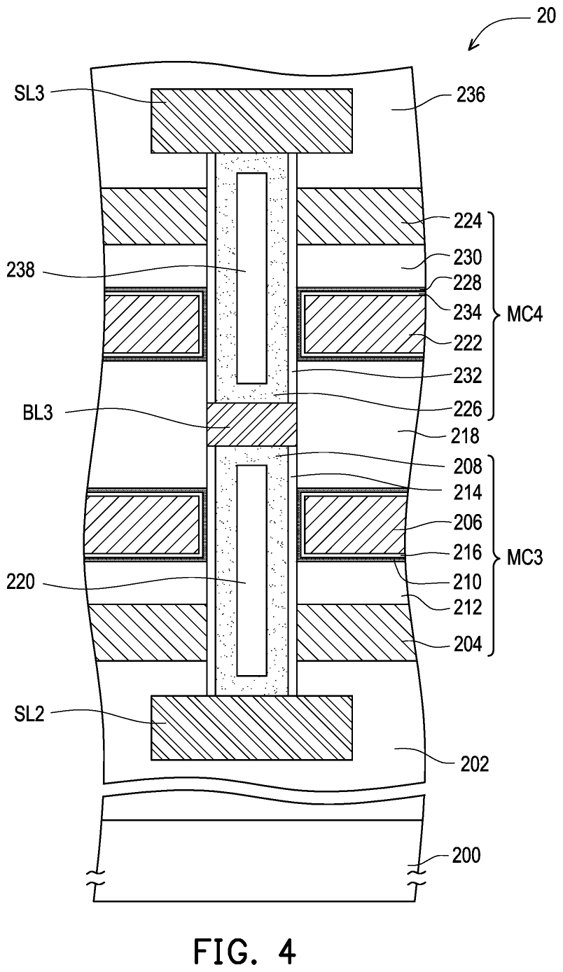

FIG. 3 is a schematic circuit diagram illustrating a memory structure according to other embodiments of the invention. FIG. 4 is a cross-sectional view of a memory cell in FIG. 3.

Referring to FIG. 3 and FIG. 4, the memory structure 20 includes a substrate 200, a dielectric layer 202, a memory cell MC3, a source line SL2, and a bit line BL3. In some embodiments, the memory structure 20 may be a 3D NOR flash memory structure. The substrate 200 may be a semiconductor substrate such as a silicon substrate. The dielectric layer 202 is disposed on the substrate 200. The dielectric layer 202 may be a single-layer structure or a multilayer structure. The material of the dielectric layer 202 is, for example, silicon oxide.

The memory cell MC3 includes a conductive layer 204, a conductive layer 206, a channel layer 208, and a charge storage layer 210. The conductive layer 204 and the conductive layer 206 are sequentially stacked on the dielectric layer 202 and are electrically insulated from each other. The conductive layer 204 can be used as a word line. The material of the conductive layer 204 is, for example, doped polysilicon. The conductive layer 206 can be used as a memory gate. The material of the conductive layer 206 is, for example, tungsten.

The channel layer 208 is disposed on one side of the conductive layer 204 and one side of the conductive layer 206. In addition, the conductive layer 204 and the conductive layer 206 are electrically insulated from the channel layer 208. In some embodiments, the conductive layer 204 may surround the channel layer 208, and the conductive layer 206 may surround the channel layer 208. The material of the channel layer 208 is, for example, a semiconductor material such as polysilicon.

The charge storage layer 210 is disposed between the conductive layer 206 and the channel layer 208. In some embodiments, the charge storage layer 210 may be further disposed between the conductive layer 206 and the conductive layer 204. The material of the charge storage layer 210 is, for example, a charge trapping material such as silicon nitride.

In some embodiments, the memory cell MC3 may further include a dielectric layer 212, a dielectric layer 214, and a dielectric layer 216. The dielectric layer 212 is disposed between the conductive layer 204 and the conductive layer 206. In some embodiments, the dielectric layer 212 may be further disposed between the conductive layer 204 and the charge storage layer 210. The material of the dielectric layer 212 is, for example, silicon oxide.

The dielectric layer 214 is disposed between the conductive layer 204 and the channel layer 208 and between the conductive layer 206 and the channel layer 208. In some embodiments, the dielectric layer 214 may be further disposed between the dielectric layer 202 and the channel layer 208 and between the dielectric layer 212 and the channel layer 208. The material of the dielectric layer 214 is, for example, silicon oxide.

The dielectric layer 216 is disposed between the charge storage layer 210 and the conductive layer 206. The material of the dielectric layer 216 is, for example, silicon oxide.

In some embodiments, the conductive layer 204 and the conductive layer 206 may be electrically insulated from each other by at least one of the dielectric layer 212, the charge storage layer 210, the and dielectric layer 216. In some embodiments, the conductive layer 204 may be electrically insulated from the channel layer 208 by the dielectric layer 214. In some embodiments, the conductive layer 206 may be electrically insulated from the channel layer 208 by at least one of the dielectric layer 214, the charge storage layer 210, and the dielectric layer 216.

The source line SL2 is disposed in the dielectric layer 202 and is connected to the channel layer 208. The material of the source line SL2 is, for example, doped polysilicon or tungsten. The bit line BL3 is disposed above the channel layer 208 and is connected to the channel layer 208. The material of the bit line BL3 is, for example, doped polysilicon or tungsten. In addition, the channel layer 208 may be disposed between the bit line BL3 and the source line SL2.

In some embodiments, the memory structure 20 may further include at least one of a dielectric layer 218 and a dielectric pillar 220. The dielectric layer 218 is disposed on the conductive layer 206. In some embodiments, the dielectric layer 218 may be disposed on the charge storage layer 210. The bit line BL3 may be disposed in the dielectric layer 218. In some embodiments, the charge storage layer 210 may be further disposed between the conductive layer 206 and the dielectric layer 218. In some embodiments, the dielectric layer 214 may be further disposed between the dielectric layer 218 and the channel layer 208. The dielectric layer 218 may be a single-layer structure or a multilayer structure. The material of the dielectric layer 218 is, for example, silicon oxide.

The dielectric pillar 220 is disposed in the channel layer 208 and is surrounded by the channel layer 208. The material of the dielectric pillar 220 is, for example, silicon oxide.

In some embodiments, the memory structure 20 may further include a memory cell MC4 and a source line SL3. The memory cell MC3 and the memory cell MC4 may be sequentially stacked on the substrate 200, thereby reducing the bit cost. In addition, the memory cell MC3 and the memory cell MC4 may share the bit line BL3. In some embodiments, the memory cell MC4 may be a mirror structure of the memory cell MC3.

The memory cell MC4 may include a conductive layer 222, a conductive layer 224, a channel layer 226, and a charge storage layer 228. The conductive layer 222 and the conductive layer 224 are sequentially stacked on the dielectric layer 218 and are electrically insulated from each other. The conductive layer 222 can be used as a memory gate. The material of the conductive layer 222 is, for example, tungsten. The conductive layer 224 can be used as a word line. The material of the conductive layer 224 is, for example, doped polysilicon.

The channel layer 226 is disposed on one side of the conductive layer 222 and one side of the conductive layer 224 and is connected to the bit line BL3. In addition, the conductive layer 222 and the conductive layer 224 are electrically insulated from the channel layer 226. In some embodiments, the conductive layer 222 may surround the channel layer 226, and the conductive layer 224 may surround the channel layer 226. The material of the channel layer 226 is, for example, a semiconductor material such as polysilicon.

The charge storage layer 228 is disposed between the conductive layer 222 and the channel layer 226. In some embodiments, the charge storage layer 228 may be further disposed between the conductive layer 224 and the conductive layer 222 and between the conductive layer 222 and the dielectric layer 218. The material of the charge storage layer 228 is, for example, a charge trapping material such as silicon nitride.

In some embodiments, the memory cell MC4 may further include a dielectric layer 230, a dielectric layer 232, and a dielectric layer 234. The dielectric layer 230 is disposed between the conductive layer 222 and the conductive layer 224. In some embodiments, the dielectric layer 230 may be further disposed between the conductive layer 224 and the charge storage layer 228. The material of the dielectric layer 230 is, for example, silicon oxide.

The dielectric layer 232 is disposed between the conductive layer 222 and the channel layer 226 and between the conductive layer 224 and the channel layer 226. In some embodiments, the dielectric layer 232 may be further disposed between the dielectric layer 230 and the channel layer 226 and between the dielectric layer 218 and the channel layer 226. The material of the dielectric layer 232 is, for example, silicon oxide.

The dielectric layer 234 is disposed between the charge storage layer 228 and the conductive layer 222. The material of the dielectric layer 234 is, for example, silicon oxide.

In some embodiments, the conductive layer 222 and the conductive layer 224 may be electrically insulated from each other by at least one of the dielectric layer 230, the charge storage layer 228, and the dielectric layer 234. In some embodiments, the conductive layer 222 may be electrically insulated from the channel layer 226 by at least one of the dielectric layer 232, the charge storage layer 228, and the dielectric layer 234. In some embodiments, the conductive layer 224 may be electrically insulated from the channel layer 226 by the dielectric layer 232.

The source line SL3 is disposed above the channel layer 226 and is connected to the channel layer 226. The material of the source line SL3 is, for example, doped polysilicon or tungsten. In addition, the channel layer 226 may be disposed between the source line SL3 and the bit line BL3.

In some embodiments, the memory structure 20 may further include at least one of a dielectric layer 236 and a dielectric pillar 238. The dielectric layer 236 is disposed on the conductive layer 224. The source line SL3 may be disposed in the dielectric layer 236. In some embodiments, the dielectric layer 232 may be further disposed between the dielectric layer 236 and the channel layer 226. The dielectric layer 236 may be a single-layer structure or a multilayer structure. The material of the dielectric layer 236 is, for example, silicon oxide.

The dielectric pillar 238 is disposed in the channel layer 226 and is surrounded by the channel layer 226. The material of the dielectric pillar 238 is, for example, silicon oxide.

In some embodiments, referring to FIG. 3, the memory structure 20 may include a plurality of memory cells MC3 and a plurality of memory cells MC4, but the number of the memory cells MC3 and the number of the memory cells MC4 are not limited to those in the figure. In addition, each memory cell MC3 and each memory cell MC4 can be independently operated. In some embodiments, although not shown in FIG. 3 and FIG. 4, the memory cells MC3 and the memory cells MC4 may be alternately stacked on the substrate 200, thereby further reducing the bit cost.

Based on the above embodiments, in the memory structure 20, the memory cell MC3 includes the conductive layer 204 and the conductive layer 206, and the conductive layer 204 and the conductive layer 206 are sequentially stacked on the dielectric layer 202 and are electrically insulated from each other. Therefore, the memory cell MC3 is a memory cell structure with a split gate, and there is no charge storage layer between the conductive layer 204 used as the word line (gate) and the channel layer 208, thereby reducing the operating voltage. In this way, the memory structure 20 can be operated at low voltage. In some embodiments, other memory cell (e.g., memory cell MC4) can be stacked on the memory cell MC3, thereby reducing the bit cost.

In summary, in the memory structure of the aforementioned embodiments, since the memory cell is a memory cell structure with a split gate, and there is no charge storage layer between the conductive layer used as the word line (gate) and the channel layer, thereby reducing the operating voltage. In this way, the memory structure can be operated at low voltage.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A memory structure, comprising:
a substrate;
a first dielectric layer disposed on the substrate;
a first memory cell comprising:
a first conductive layer and a second conductive layer sequentially stacked on the first dielectric layer and electrically insulated from each other;
a first channel layer disposed on one side of the first conductive layer and one side of the second conductive layer, wherein the first conductive layer and the second conductive layer are electrically insulated from the first channel layer; and
a first charge storage layer disposed between the first conductive layer and the first channel layer;
a first bit line disposed in the first dielectric layer and connected to the first channel layer; and
a source line disposed above the first channel layer and connected to the first channel layer.

2. The memory structure according to claim 1, wherein the memory structure comprises a three-dimensional (3D) NOR flash memory structure.

3. The memory structure according to claim 1, wherein the first channel layer is disposed between the source line and the first bit line.

4. The memory structure according to claim 1, wherein
the first memory cell further comprises:
a second dielectric layer disposed between the first conductive layer and the second conductive layer;
a third dielectric layer disposed between the first conductive layer and the first channel layer and between the second conductive layer and the first channel layer; and
a fourth dielectric layer disposed between the first charge storage layer and the first conductive layer, and
the memory structure further comprises:
a fifth dielectric layer disposed on the second conductive layer, wherein the source line is disposed in the fifth dielectric layer.

5. The memory structure according to claim 4, further comprising:
a second memory cell comprising:
a third conductive layer and a fourth conductive layer sequentially stacked on the fifth dielectric layer and electrically insulated from each other;
a second channel layer disposed on one side of the third conductive layer and one side of the fourth conductive layer and connected to the source line, wherein the third conductive layer and the fourth conductive layer are electrically insulated from the second channel layer; and
a second charge storage layer disposed between the fourth conductive layer and the second channel layer; and
a second bit line disposed above the second channel layer and connected to the second channel layer.

6. The memory structure according to claim 5, wherein the first memory cell and the second memory cell are sequentially stacked on the substrate.

7. The memory structure according to claim 5, wherein the first memory cell and the second memory cell share the source line.

8. The memory structure according to claim 5, wherein the second channel layer is disposed between the second bit line and the source line.

9. The memory structure according to claim 5, wherein
the second memory cell further comprises:
a sixth dielectric layer disposed between the third conductive layer and the fourth conductive layer;
a seventh dielectric layer disposed between the third conductive layer and the second channel layer and between the fourth conductive layer and the second channel layer; and
an eighth dielectric layer disposed between the second charge storage layer and the fourth conductive layer, and
the memory structure further comprises:
a ninth dielectric layer disposed on the fourth conductive layer, wherein the second bit line is disposed in the ninth dielectric layer.

10. The memory structure according to claim 5, further comprising:
a first dielectric pillar disposed in the first channel layer and surrounded by the first channel layer; and
a second dielectric pillar disposed in the second channel layer and surrounded by the second channel layer.

11. A memory structure, comprising:
a substrate;
a first dielectric layer disposed on the substrate;
a first memory cell comprising:
a first conductive layer and a second conductive layer sequentially stacked on the first dielectric layer and electrically insulated from each other;
a first channel layer disposed on one side of the first conductive layer and one side of the second conductive layer, wherein the first conductive layer and the second conductive layer are electrically insulated from the first channel layer; and
a first charge storage layer disposed between the second conductive layer and the first channel layer;
a first source line disposed in the first dielectric layer and connected to the first channel layer; and
a bit line disposed above the first channel layer and connected to the first channel layer.

12. The memory structure according to claim 11, wherein the memory structure comprises a 3D NOR flash memory structure.

13. The memory structure according to claim 11, wherein the first channel layer is disposed between the bit line and the first source line.

14. The memory structure according to claim 11, wherein
the first memory cell further comprises:
a second dielectric layer disposed between the first conductive layer and the second conductive layer;
a third dielectric layer disposed between the first conductive layer and the first channel layer and between the second conductive layer and the first channel layer; and
a fourth dielectric layer disposed between the first charge storage layer and the second conductive layer, and
the memory structure further comprises:
a fifth dielectric layer disposed on the second conductive layer, wherein the bit line is disposed in the fifth dielectric layer.

15. The memory structure according to claim 14, further comprising:
a second memory cell comprising:
a third conductive layer and a fourth conductive layer sequentially stacked on the fifth dielectric layer and electrically insulated from each other;
a second channel layer disposed on one side of the third conductive layer and one side of the fourth conductive layer and connected to the bit line, wherein the third conductive layer and the fourth conductive layer are electrically insulated from the second channel layer; and
a second charge storage layer disposed between the third conductive layer and the second channel layer; and
a second source line disposed above the second channel layer and connected to the second channel layer.

16. The memory structure according to claim 15, wherein the first memory cell and the second memory cell are sequentially stacked on the substrate.

17. The memory structure according to claim 15, wherein the first memory cell and the second memory cell share the bit line.

18. The memory structure according to claim 15, wherein the second channel layer is disposed between the second source line and the bit line.

19. The memory structure according to claim 15, wherein
the second memory cell further comprises:
a sixth dielectric layer disposed between the third conductive layer and the fourth conductive layer;
a seventh dielectric layer disposed between the third conductive layer and the second channel layer and between the fourth conductive layer and the second channel layer; and
an eighth dielectric layer disposed between the second charge storage layer and the third conductive layer, and
the memory structure further comprises:
a ninth dielectric layer disposed on the fourth conductive layer, wherein the second source line is disposed in the ninth dielectric layer.

20. The memory structure according to claim 15, further comprising:
a first dielectric pillar disposed in the first channel layer and surrounded by the first channel layer; and
a second dielectric pillar disposed in the second channel layer and surrounded by the second channel layer.
